(19) United States
(12) Patent Application Publication
(10) Pub. No.: US 2011/0175504 A1
(43) Pub. Date: Jul. 21, 2011

(54) DOOR AND SIDE PANELS

(76) Inventor: Michael Cook, Bedfordshire (GB)

(21) Appl. No.: 13/000,195

(22) PCT Filed: Jun. 19, 2009
(86) PCT No.: PCT/GB09/50701

§ 371 Date: Mar. 28, 2011

(30) Foreign Application Priority Data
Jun. 20, 2008 (GB) 0811371.4

(51) Int. Cl. H05K 5/02; E06B 7/04

(52) U.S. Cl. 312/236; 49/70

(57) ABSTRACT

There is provided a door or side panel for a cabinet for storing data processing or telecommunications equipment, the door or side panel comprising a first vertical face and an opposing second vertical face, a first vertical side and an opposing second vertical side, and a first horizontal side and an opposing second horizontal side; the door or side panel further comprising at least one partition means positioned between the first and second vertical faces, and also comprising at least one air passage arranged so that air may pass through the door or side panel from the first vertical face, past the partition means, to the second vertical face, or from the second vertical face, past the partition means, to the first vertical face. There is also provided a cabinet for storing data processing or telecommunications equipment comprising one or more door or side panels of the invention.

The present invention relates to door or side panels for cabinets for storing data processing or telecommunications equipment, and cabinets including such panels.

In recent years the amount of electrical equipment used in offices has increased dramatically and it has become common practice to store such equipment, particularly data processing and telecommunications equipment, in purpose built racks, which may themselves be housed in purpose built enclosures or cabinets. Various standards for such racks and cabinets have developed, so that cabinets from different sources are normally compatible with electrical equipment from a wide range of manufacturers. One widely adopted standard for electrical equipment for storage is known as the “19 inch rack” or “19 inch rack enclosure”, in which most conventional telecommunications or data processing equipment may be stored.

A common problem in storing electrical equipment in such cabinets however, is the accumulation of heat caused by storing a number of heat producing pieces of equipment in a closed container. Storing large amounts of electrical equipment having moving parts (for example cooling fans) in a closed container can also lead to the generation of unacceptable noise levels. Various approaches to dealing with one or both of the above problems have been made, although none have been completely satisfactory to date.

One approach to the problem of heat accumulation is to provide cabinets having passages allowing air to flow into the cabinet from the surroundings through various panels to cool the interior, and for the heated air to flow out of the cabinet through further passages. Such cabinets may be “passive”, relying simply on the fans present in the equipment contained in the cabinet, or may include additional fans to assist in pulling air into the cabinet and/or the removal of heated air from the cabinet. Such cabinets may have reasonable cooling efficiency, but often suffer from unacceptable noise levels, even when the cabinets are lined with sound absorbing materials.

Other approaches to cooling equipment cabinets have included the use of cooling water or gases, for example carbon dioxide.

One approach to the reduction of noise, is to include noise generators inside the cabinet or cooling system which are controlled to generate “anti-noise”, so as to neutralise the noise produced by the equipment contained in the cabinet. Such a solution however, adds additional complexity to the build, uses valuable rack space and adds unnecessary costs.

Further approaches to the reduction of noise have concentrated on directing air flow from the front of the cabinet to the rear, and ensuring that air leaves the cabinet via the rear wall. This approach is effective in many cases as, in general, up to 80% of the noise generated inside a cabinet will be generated towards the sides or rear, rather than the front, however this approach is not always effective, even when combined with the use of sound absorbing materials and/or structures, as sound may escape from the front of the cabinet via channels present to permit the ingress of cooling air.

The present invention provides a door or side panel for a cabinet for storing data processing or telecommunications equipment, the door or side panel comprising a first vertical face and an opposing second vertical face, a first vertical side and an opposing second vertical side, and a first horizontal side and an opposing second horizontal side; the door or side panel further comprising at least one partition means positioned between the first and second vertical faces, and also comprising at least one air passage arranged so that air may pass through the door or side panel from the first vertical face, past the partition means, to the second vertical face, or from the second vertical face, past the partition means, to the first vertical face.

Door panels or side panels (sometimes referred to herein simply as panels) of the present invention are suitable for use as doors (either singly or in pairs) or as wall elements of cabinets for storing data processing or telecommunications equipment.

In a first preferred embodiment of a door or side panel of the present invention, the at least one partition means is generally parallel to the first and second vertical faces, so that a first plenum chamber is formed between the first vertical face and the partition means, and a second plenum chamber is formed between the second vertical face and the partition means, and the first and second plenum chambers are in fluid communication.

In door or side panels of the present invention, it is preferred that the partition means and one or more air passages are arranged so that sufficient volumes of air may pass through the panels to provide a cooling effect when the panels are attached to a cabinet containing data processing or telecommunications equipment. It is also preferred that, for air to pass through the panel, it must travel a distance greater than the thickness of the panel, and ideally up to a distance of more than one and a half times the width of the panel. It is also preferable that air flowing through panels of the present invention should be required to change direction at least once, reducing the chances of noise passing along the air passage in the reverse direction to the passage of the air.

In a first preferred arrangement of a panel of the first embodiment of the present invention, the panel comprises an opening to the first plenum chamber located on the first vertical face adjacent to the first vertical side, or located on the first vertical side, and an opening to the second plenum chamber located on the second vertical face adjacent to the first vertical side, or located on the first vertical side, and further comprises means linking the first plenum chamber to the second plenum chamber located adjacent to the second vertical side.

In a second preferred arrangement of a panel of the first embodiment of the present invention, the panel comprises an opening to the first plenum chamber located on the first vertical face at or adjacent to the mid point between the first and second vertical sides, and an opening to the second plenum chamber located on the second vertical face at or adjacent to the mid point between the first and second vertical sides, and further comprises a first means linking the first and second plenum chambers located adjacent to the first vertical side and a second means linking the first and second plenum chambers located adjacent to the second vertical side.

Door or side panels of the first embodiment of the present invention may also comprise multiple openings to the first and/or second plenum chambers, as long as the majority of the air passing through the panel is required to change direction at least once when passing through the panel. In a third preferred arrangement of a panel of the first embodiment of the present invention therefore, the door or side panel comprises a first opening to the first plenum chamber located on the first vertical face adjacent to the first vertical side, or located on the first vertical side, and a second opening to the first plenum chamber located on the first vertical face adjacent to the second vertical side, or located on the second vertical side; and further comprises a first opening to the second plenum chamber located on the second vertical face adjacent to the first vertical side, or located on the first vertical side, and a second opening to the second plenum chamber located on the second vertical face adjacent to the second vertical side, or located on the second vertical side; and means linking the first plenum chamber to the second plenum chamber located at or adjacent to the mid point between the first and second vertical sides.

In an alternative arrangement of a panel of the first embodiment of the present invention, air is required to pass vertically from the top to the bottom of the panel, and then from the bottom to the top of the panel before exiting (or vice versa). In a fourth preferred arrangement of a panel of the first embodiment of the present invention therefore, the door or side panel comprises an opening to the first plenum chamber located on the first vertical face adjacent to the first horizontal side, or located on the first horizontal side, and an opening to the second plenum chamber located on the second vertical face adjacent to the first horizontal side, or located on the first horizontal side, and means linking the first plenum chamber to the second plenum chamber located adjacent to the second horizontal side.

Panels according to the fourth arrangement of the first embodiment of the present invention preferably also include fans to assist in drawing air into the panel from the interior of the cabinet to which the panel is attached through the front face of the panel and out of the cabinet through the rear face of the panel. All types of fans suitable for moving appropriate quantities of air (depending upon the size of the cabinets to which the cabinets will be attached) may be used in panels according to the fourth arrangement of the first embodiment of the present invention, including backward curved centrifugal fans, EC and Hall Effect fans and axial fans. The fans may be AC or DC powered. A particularly suitable fan is an AC, 230v, 0.29 A, 590 m³/h, 59 dBA backward curved centrifugal fan.

Door or side panels according to the present invention may also comprise multiple independent air passages. There is therefore provided a second embodiment of a door or side panel of the present invention, wherein the at least one partition means is generally parallel to the first and second vertical faces, and which further comprises dividing means positioned between the first and second vertical faces and being generally perpendicular thereto, so that non-interconnected first and second plenum chambers are formed between the first vertical face and the partition means and non-interconnected third and fourth plenum chambers are formed between the second vertical face and the partition means; the door or side panel further comprising a first passage allowing air to pass through the door or side panel from the first vertical face, past the partition means, to the second vertical face through the first and third plenum chambers, or from the second vertical face, past the partition means, to the first vertical face through the third and first plenum chambers; and a second air passage allowing air to pass from the first vertical face, past the partition means, to the second vertical face through the second and fourth plenum chambers, or from the second vertical face, past the partition means, to the first vertical face through the fourth and second plenum chambers; the door or side panel further comprising first linking means connecting the first and third plenum chambers and second linking means connecting the second and fourth plenum chambers.

In a preferred arrangement of a door or side panel of the second embodiment of the present invention, the door or side panel comprises an opening to the first plenum chamber located on the first vertical face adjacent to the first vertical side, or located on the first vertical side, and an opening to the third plenum chamber located on the second vertical face adjacent to the first vertical side, or located on the first vertical side, the linking means connecting the first and third plenum chambers being located adjacent to the dividing means; and further comprises an opening to the second plenum chamber located on the first vertical face adjacent to the second vertical side, or located on the second vertical side, and an opening to the fourth plenum chamber located on the second vertical face adjacent to the second vertical side, or located on the second vertical side, the linking means connecting the second and fourth plenum chambers being located adjacent to the dividing means.

The openings to the plenum chamber of the door or side panels of the present invention may be of any size suitable to permit the passage of suitable volumes of air through the panels, but should not be so large that sound may easily pass back through the panels in a direction opposite to that of the flow of air. In panels of the present invention having openings to the plenum chambers located on or adjacent to the vertical sides of the panel, or located at or adjacent to the mid-point between the first and second vertical sides, the openings preferably extend for substantially the full height of the panels. The widths of the openings to the plenum chambers in such panels of the present invention may be uniform or may vary over the length of the openings, but are preferably uniform. It is also preferred that where the openings to the plenum chambers extend for substantially the full height of the panels, the average widths of the openings will be between 15 and 50 mm, more preferably between 20 and 40 mm, for example 30.5 mm. Where the openings to the plenum chambers extend for less than the full height of the panels, the average widths of the openings will increase proportionally to maintain the above ratio. Similarly, in panels of the present invention having openings to the plenum chambers located on or adjacent to the horizontal sides of the panels, the openings preferably extend for substantially the full width of the panels. The widths of the openings to the plenum chambers in such panels may again be uniform or may vary, but it is preferred that they are generally uniform over their entire length. It is also preferred that the widths of the openings in such panels are selected so that the surface area of the openings will be between 0.01 m² and 0.04 m², for example 0.0157 m² or 0.0314 m².

In door or side panels of the present invention the means linking the various plenum chambers preferably comprises one or more passages through the partition means between the chambers. The numbers and sizes of such passages may vary, but are preferably selected so that a suitable volume of air may pass through the panel, but also so that air passing through the panel is required to travel a substantial distance and preferably to change direction at least once. In panels according to the present invention having means linking the plenum chambers located adjacent to the vertical sides or adjacent to the mid-point between the vertical sides, the linking passages preferably extend for substantially the full height of the panel. Similarly, for door or side panels of the present invention having means linking the plenum chambers located adjacent to the horizontal sides, the linking passages preferably extend for substantially the full width of the panel. The widths of the linking passages may be uniform or may vary over their length, but are preferably generally uniform. The widths of the linking passages are also preferably selected so that the total area of all linking passages is equivalent to roughly half (for example between 40 and 60%) of the total area of openings to the plenum chambers. Thus it is preferred that, in use, the total area through which air may enter a panel of the invention is generally equivalent to the total area of linking passages, and also equivalent to the total area through which air may leave the panel.

In door or side panels of the present invention comprising plenum chambers, it is preferred that these chambers occupy substantially the entire volume of the panels.

Door or side panels of the present invention may be made from any suitable materials, for example wood, aluminium or steel. The panels may be made from a single piece of material, for example by folding and pressing, or may be made as composites of the same or different materials. As an example, a basic substructure may be manufactured from mild steel, to which surface panels of wood, or wood composite, may be attached.

Door or side panels of the present invention may be of any suitable size for use in cabinets for storing data processing or telecommunications equipment; the height and width being governed by the size of the cabinet to which they are to be attached, and the thickness being governed by the size of the plenum chambers contained in the panel. Preferably, the door or side panels of the present invention are suitable for use in cabinets conforming to the “19 inch rack” standard. In a particularly preferred embodiment, the panels of the present invention have a width of approximately half the width of the cabinet to which they are to be attached, so that two panels may be used to form a pair of doors on a face of the cabinet. This arrangement reduces the weight of each door, and assists in access to the contents of the cabinet.

Door or side panels of the present invention preferably also comprise sound absorbing materials, for example in the form of sheets or layers. Any conventional sound absorbing materials may be used, for example single or multiple layers of foam or rubber. A particularly preferred sound absorbing material is open cell synthetic rubber bonded with polyurethane. The sheets or layers of sound absorbing materials may be located on any surfaces of the panels, but are particularly preferably included on at least one of: the inside surface of the front face, one or both sides of the partition means, or one or both sides of the inside face. Most preferably sheets or layers of sound absorbing materials are included on all of these surfaces.

Door or side panels of the present invention preferably also comprise sound absorbing materials in the form of vertical strips, which act to increase the distance that sound must travel to pass out of the panels, as well as to absorb any such sound, and to therefore further reduce the amount of sound passing out of cabinets comprising doors or panels of the invention. In particular, in door or side panels of the first, second or third arrangements of the first embodiment of the present invention, the first plenum chamber preferably comprises at least one vertical strip of sound absorbing material extending for the full height of the plenum chamber. In such doors or panels, the or each vertical strip of sound absorbing material preferably projects into the first plenum chamber to a distance of between 40 and 75% of the width of the chamber, more preferably between 50 and 60%, for example 52% or 58%.

Particularly preferred panels according to the first, second and third arrangements of the first embodiment of the present invention comprise at least one vertical strip of sound absorbing material located on the inside surface of the first vertical face and at least one vertical strip of sound absorbing material located on the opposing face of the partition means, the or each vertical strip of sound absorbing material located on the inside surface of the first vertical face being located at a position other than directly opposite a vertical strip of sound absorbing material located on the opposing face of the partition means. A particularly preferred panel comprises two vertical strips of sound absorbing material located on the inside surface of the first vertical face, and two vertical strips of sound absorbing material located on the opposing face of the partition means, each vertical strip of sound absorbing material projecting into the first plenum chamber to a distance of between 50% and 60% of the width of the chamber.

The vertical sound absorbing strips may comprise any conventional sound absorbing materials, for example single or multiple layers of foam or rubber. A particularly preferred sound absorbing material is open cell synthetic rubber bonded with polyurethane.

The present invention further provides cabinets for storing data processing or telecommunications equipment comprising one or more door or side panels of the present invention.

Cabinets of the present invention may be of any suitable size for containing data processing or telecommunications equipment, but preferably conform to one or more standards, for example the “19 inch rack” standard.

Cabinets according to the present invention may be free standing or wall mounted. Free standing cabinets and wall mounted cabinets preferably have a door comprising one or a pair of panels according of the present invention, most preferably a pair of panels according to the first arrangement of the first embodiment of the invention. Free standing cabinets of the present invention preferably also comprise a rear wall or door comprising one or a pair of panels of the present invention, most preferably a door comprising two panels according to the first arrangement of the first embodiment of the present invention or a door or wall comprising one or two panels according to the fourth arrangement of the first embodiment of the present invention.

Wall mounted cabinets of the present invention may comprise rear walls or doors comprising on or more panels of the present invention, or conventional door or wall panels designed to allow the egress of air from the interior of the cabinet.

In a first preferred embodiment of a cabinet of the present invention, the cabinet comprises a door comprising a pair of panels of the present invention and an opposing door or wall comprising one or two panels of the present invention. In this embodiment, each of the panels of the present invention are preferably panels according to the first arrangement of the first embodiment of the present invention.

In a second preferred embodiment of a cabinet of the present invention, the cabinet comprises a door comprising two panels according to the first arrangement of the first embodiment of the present invention, and an opposing rear wall or door comprising one or a pair of panels according to the fourth arrangement of the first embodiment of the present invention. In this second embodiment, the cabinet also includes one or more fans drawing air from the interior of the cabinet into the rear panel or panels and out of the rear panel or panels towards the rear of the cabinet. These fans may be positioned anywhere in the cabinet, but are preferably positioned inside the rear panel or panels.

Embodiments of the present invention will now be described by way of example, by reference to the following drawings in which:

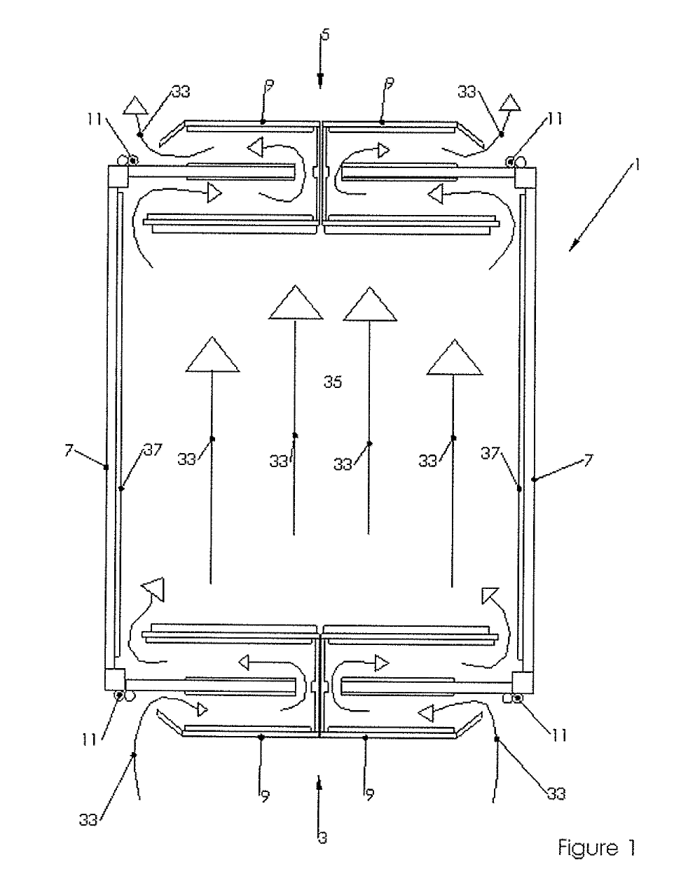

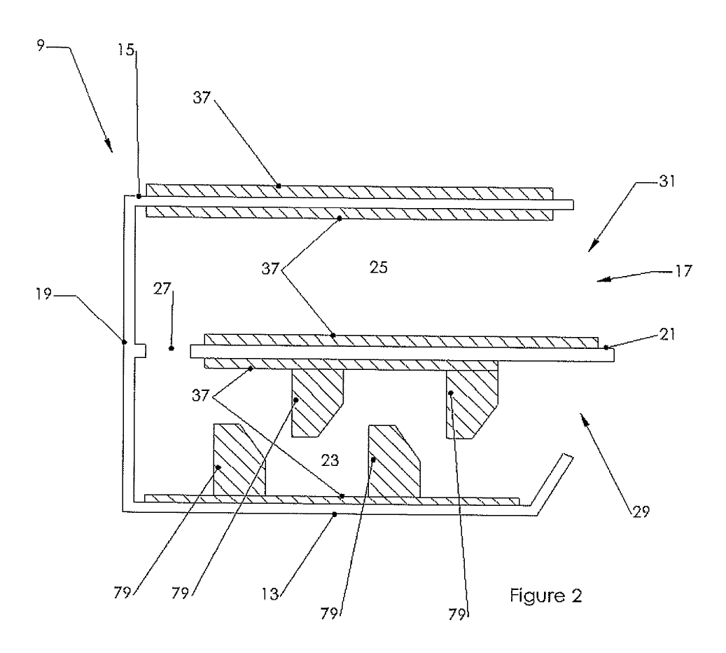

FIG. 1 is a plan view of a first embodiment of a cabinet of the present invention comprising 2 pairs of doors according to the embodiment shown in FIG. 2;

FIG. 2 is a plan view of a first arrangement of an embodiment of a cabinet door of the present invention;

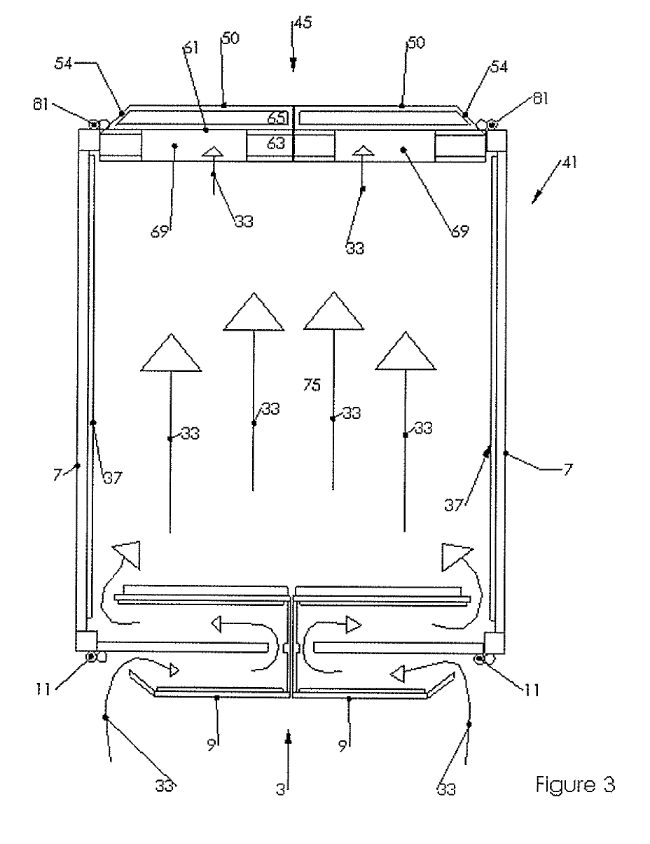

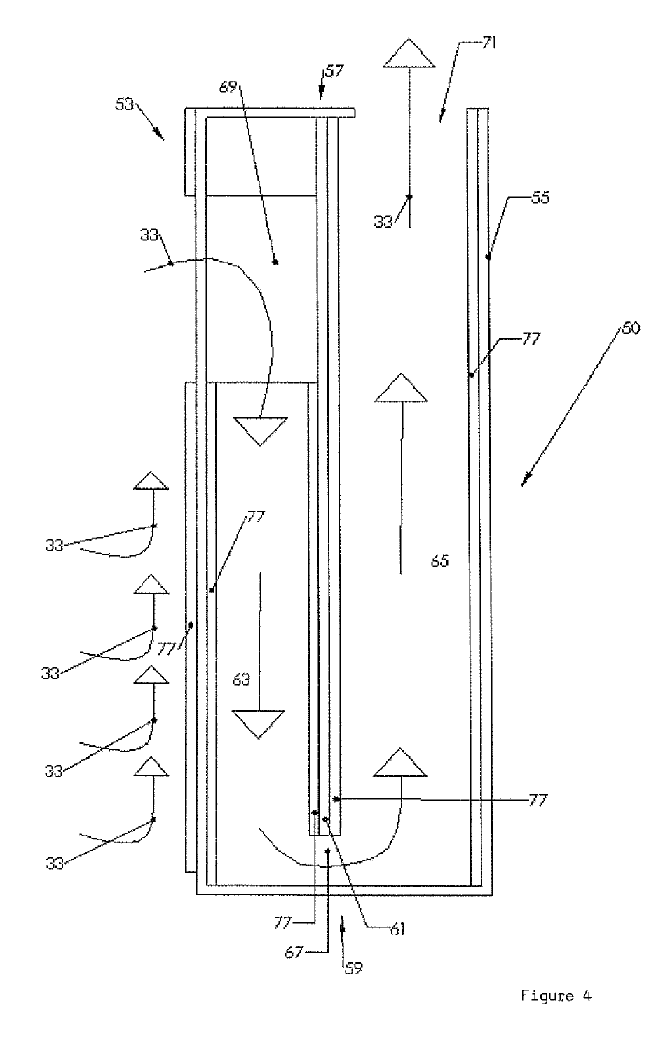

FIG. 3 is a plan view of a second embodiment of a cabinet according to the present invention comprising a first pair of doors according to the embodiments shown in FIG. 2 and a second pair of doors according to the embodiment shown in FIG. 4, and

FIG. 4 is a side view of a fourth arrangement of an embodiment of a door according to the present invention.

FIG. 1 shows a plan view of a first embodiment of a cabinet 1 of the present invention. The cabinet 1 has a front 3 and a rear 5, plus two linking sides 7. The front 3 comprises a pair of doors 9, each door 9 being a first arrangement of a first embodiment of a panel according to the present invention. The rear 5 also comprises a pair of doors 9, each of which is a first arrangement of a first embodiment of a panel of the present invention. Each of the doors 9 are joined to one of the walls 7 by hinges 11. Each pair of doors 9 meet in the closed position to provide a noise proof seal to the cabinet 1.

As shown in FIG. 2, each of the doors 9 of the cabinet 1 comprises a first vertical face 13 and a second vertical face 15. Each door 9 also comprises a first vertical side 17 and a second vertical side 19. The top and bottom of each door 9 is sealed by a first horizontal side and a second horizontal side respectively (not shown). Each door 9 also comprises a partition 21 located between the first vertical face 13 and the second vertical face 15 extending for the whole height of the door 9 and being connected to the first and second horizontal sides at each end. The first vertical face 13, first vertical side 17, second vertical side 19 and the partition 21, together with the first and second horizontal sides form a first plenum chamber 23. The second vertical face 15, first vertical side 17, second vertical side 19 and the partition 21, together with the first and second horizontal sides form a second plenum chamber 25. The partition 21 also comprises a passage 27 linking the first plenum chamber 23 and the second plenum chamber 25. The passage 27 runs for substantially the full height of the door and has a uniform width of 30.5 mm. The door 9 also comprises an opening 29 to the first plenum chamber 23 and an opening 31 to the second plenum chamber 25, both openings being positioned on the first vertical side 17. Each of the openings 29, 31 run for the full height of the door 9 and have a uniform width of 30.5 mm.

As shown in FIG. 1, air 33 enters both of the front door panels 9 from the exterior of the cabinet 1 via opening 29. The air 33 passes through the first plenum chamber 23 and around partition 21, via passage 27, into second plenum chamber 25. The air exits the second plenum chamber 25 via the opening 31, and is vented into the interior 35 of the cabinet 1. In use, air is drawn into the cabinet 1 via fans contained in the equipment stored in the cabinet 1. In an alternative embodiment however, additional fans can be included in the cabinet 1 to draw air into the interior 35.

In use, air 33 passes through the interior 35 of the cabinet and is heated by the equipment contained therein. This heated air 33 then passes out of the cabinet 1 through the doors 9 positioned at the rear 5 of the cabinet 1. In the first embodiment of the cabinet of the invention shown in FIG. 1, the rear doors 9 are of similar construction to the front doors 9, but in this arrangement air passes through these doors in the reverse direction. Thus, air enters the rear doors 9 via the opening 31 into the second plenum chamber 25, passes through the second plenum chamber 25 and around the partition 21, via the passage 27, and into the first plenum chamber 23. The air then exits to the exterior of the cabinet 1 through the opening 29 from the first plenum chamber 23.

In the first embodiment of a cabinet of the invention each of the doors 9 are made from mild steel, but in alternative embodiments they could be made from wood, aluminium or mixtures thereof, for example a steel sub-frame with wood panels attached. The sides 7 of the cabinet 1 are constructed from conventional side panels used in cabinets for storing data processing or telecommunications equipment, and in the present embodiment they are also constructed from mild steel.

The first embodiment of the cabinet 1 of the present invention also comprises sheets or layers of sound absorbing foam 37 comprising an open cell synthetic rubber bonded with polyurethane. As shown in FIGS. 1 and 2, the sound absorbing material 37 is included in each of the doors 9 as layers on the inside surface of the first vertical face 13, both faces of the partition 21 and both faces of the second vertical face 15. Layers of sound absorbing material 37 are also included on the inside face of each of the sides 7 of the cabinet 1. In alternative embodiments only one or two of these surfaces may include the sound absorbing material 37.

Each of the doors 9 of the first embodiment of the cabinet 1 may optionally also comprise vertical strips of sound absorbing material 79 located inside the first plenum chamber 23. These strips are preferably arranged to further reduce the amount of sound transmitted out of the cabinet 1 by the door 9, but not to substantially reduce the flow of air 33 passing into or out of the interior 35 of the cabinet 1 via the doors 9. As shown in FIG. 2, two vertical strips of sound absorbing materials 79 are preferably located on the inside surface of the first vertical face 13, and two further vertical strips of sound absorbing material 79 are located on the opposing face of the partition 21. In this arrangement, each of the vertical strips of sound absorbing material 79 project into the plenum chamber 23 to a distance of 55% of the width of the plenum chamber 23, and each vertical strip of sound absorbing material 79 is positioned so that it is not directly opposite an opposing vertical strip 79. The vertical strips of sound absorbing material 79 extend for the full height of the first plenum chamber 23. Ideally, the vertical strips of sound absorbing material 79 are also shaped to provide less resistance to the flow of air 33 into the plenum chamber in the intended direction, and greater resistance for the flow of air into the plenum chamber in the non-intended direction. Thus, as shown in FIG. 2, in a door 9 intended for use at the front 3 of a cabinet 1 according to the first embodiment of the invention, the vertical strips 79 will include tapering faces in the direction of the opening 29 through which air enters the first plenum chamber 23, but will have vertical faces in the direction of the passage 27 through the partition 21. Thus, in this arrangement the flow of air 33 into the interior 35 of the cabinet 1 through the doors 9 will not be greatly restricted by the vertical strip 79, whilst greater resistance will be provided by the strip 79 to the flow of air 33 from the interior 35 of the cabinet 1 out through the door 9, which will also reduce the amount of sound able to escape from the cabinet 1 through the front doors 9. This arrangement may be reversed in doors 9 for use at the rear 5 of the cabinet 1 according to the first embodiment of the present invention.

In use, most of the noise generated inside the cabinet 1 will be carried towards the rear 5 of the cabinet 1 due to the flow of air 33 through the interior 35 of the cabinet 1. The noise will then be absorbed by the sound absorbing material 37 in the rear doors 9 of the cabinet 1, or vented through the rear 5 of the cabinet 1. Any noise travelling towards the front 3 of the cabinet 1 will be absorbed by the sheets of sound absorbing material 37 on the inside face of the front doors 9 of the cabinet 1, or will be reflected back towards the rear 5 of the cabinet. Any noise passing into the doors 9 at the front 3 of the cabinet 1 will either be absorbed by the sheets or vertical strips 79 of sound absorbing materials contained in the doors 9, or will also be prevented from passing through the doors 9 by the partition 21.

A second embodiment of a cabinet 41 of the present invention is shown in FIG. 3. In this embodiment, the cabinet 41 has a front 3 comprising a pair of doors 9 according to the first arrangement of the first embodiment of a panel of the present invention discussed with respect to FIGS. 1 and 2, and a rear 45 comprising a pair of doors 50 according to a fourth arrangement of a first embodiment of a panel of the present invention, shown in more detail in FIG. 4. The cabinet 41 also comprises sides 7, as discussed with respect to the first embodiment of the cabinet of the present invention. As shown in FIGS. 3 and 4, the rear doors 50 each comprise a first vertical face 53 and a second vertical face 55, plus a first horizontal side 57 and a second horizontal side 59. Each rear door 50 also comprises a first vertical side 54 and an opposing second vertical side. Each rear door 50 comprises a partition 61 located between the first vertical face 53 and the second vertical face 55. The partition 61 runs the full width of the door 50 from the first vertical side 54 to the second vertical side, and substantially the full height of the door 50 from the first horizontal side 57 to near to the second horizontal side 59, forming a first plenum chamber 63 and a second plenum chamber 65. A passage 67 is provided through the partition 61 linking the first plenum chamber 63 with the second plenum chamber 65. The passage 67 runs for substantially the full width of the door 50 and has an area of 0.0157 m². Each rear door 50 includes an opening 71 to the second plenum chamber 65 located on the first horizontal side 57. The opening 71 runs for substantially the full width of the door 50 and has a surface area of 0.0157 m².

Each rear door 50 is also provided with a fan 69 which draws air 33 into the first plenum chamber 63. The fan 69 is an AC, 230v, 0.29 A, 590 m³/h, 59 dBA backward curved centrifugal fan. Air 33 is drawn into each door 50 by the fan 69 and passes through the first plenum chamber 63, around the partition 61, through the passage 67 and into the second plenum chamber 65. The air exits each door 50 through the opening 71 from the second plenum chamber 65 towards the rear of the cabinet 41. Each rear door 50 is made of mild steel, but in alternative embodiments could be made from any material, for example aluminium or wood, or combinations thereof, for example a steel substructure with wooden panels.

In use, air 33 passes into the second embodiment of a cabinet 41 of the present invention through the front doors 9, as discussed with respect to the first embodiment of the cabinet of the present invention. The air 33 passes through the interior 75 of the cabinet 41 and is heated by the equipment contained therein. The air is pulled towards the rear 45 of the cabinet 41 by the fans 69 located in the rear doors 50. Air striking the first vertical face 53 of each door 50 is pulled up to the fans 69 and into the first plenum chamber 63 of each rear door. The air 33 then passes around the partition 61, through the passage 67, into the second plenum chamber 65, and out of each rear door 50 through the opening 71. Whilst the heated air 33 passes through the second plenum chamber, it heats the second vertical face 55 of each rear door 50, which radiates heat into the ambient atmosphere, helping to cool the air 33. Each rear door 50 also includes sound absorbing layers 77 comprising an open cell synthetic rubber bonded with polyurethane. The sound absorbing layers 77 are located on both sides of the first vertical face 53, both sides of the partition 61 and the interior face of the second vertical face 55. In alternative embodiments only one or two of the above surfaces may comprises sound absorbing layers 77.

In use, noise generated in the interior 75 of the second embodiment of the cabinet 41 will be directed towards the rear 45 of the cabinet 41, and will be absorbed by the sound absorbing material 77 contained in the rear doors 50, or transferred out of the rear of the cabinet. Sound projected towards the front 43 of the cabinet 41 will be absorbed or reflected by the doors 9, as discussed above with respect to the first embodiment of the cabinet of the present invention.

Each of the rear doors 50 are attached to one of the walls 7 of the cabinet 41 by hinges 81 at the first vertical edge 54. The pair of rear doors 50 meet in the closed position at their second vertical edges to provide a noise proof seal to the cabinet 41. In alternative embodiments, the pair of rear doors 50 could be replaced by a single door or fixed panel having the same basic structure as the rear doors 50 discussed above, but having double the width and comprising two fans.

The effectiveness of cabinets according to the present invention in reducing the transmission of sound from the interior to the exterior may be tested by standard method ISO 3744 (Sound Power Measurements on Computer Cabinets). When cabinets are tested using a sound power of 97.3 decibels (dBA) standard metal cabinets produce a reduction of only 2 dBA. In contrast, a cabinet corresponding to the first embodiment of the invention shown in FIG. 1 produces a reduction of 28 dBA and a cabinet corresponding to the second embodiment of the invention shown in FIG. 3 produces a reduction of 28.5 dBA. In addition, further reductions in sound transmission may be achieved by incorporating vertical strips of sound absorbing materials in the front and/or rear doors of the cabinet corresponding to the first embodiment of the invention, and in the front doors of the cabinet corresponding to the second embodiment of the invention.

1-17. (canceled)

18. A door or side panel for a cabinet for storing data processing or telecommunications equipment, the door or side panel comprising at least one air passage therethrough defined by:
a first vertical face and an opposing second vertical face;
a first vertical side and an opposing second vertical side;
a first horizontal side and an opposing second horizontal side;
the at least one airflow passage of the door or side panel further defined by at least one partition positioned between the first and second vertical faces, and the at least one air passage arranged so that air may pass through the door or side panel from the first vertical face, past the partition, to the second vertical face, or from the second vertical face, past the partition, to the first vertical face;
wherein a first plenum chamber is formed between the first vertical face and the partition, and a second plenum chamber is formed between the second vertical face and the partition, the first and second plenum chambers being in fluid communication;
the door or side panel further comprising an opening to the first plenum chamber located on the first vertical face adjacent to the first vertical side, or located on the first vertical side, or located at or adjacent to the mid point between the first and second vertical sides, and an opening to the second plenum chamber located on the second vertical face adjacent to the first vertical side, or located on the first vertical side, or located at or adjacent to the mid point between the first and second vertical sides and further comprising a passage linking the first plenum chamber to the second plenum chamber located adjacent to the second vertical side and/or located adjacent to the first vertical side;
or the door or side panel further comprising a first opening to the first plenum chamber located on the first vertical face adjacent to the first vertical side, or located on the first vertical side, and a second opening to the first plenum chamber located on the first vertical face adjacent to the second vertical side, or located on the second vertical side; the door or side panel further comprising a first opening to the second plenum chamber located on the second vertical face adjacent to the first vertical side, or located on the first vertical side, and a second opening to the second plenum chamber located on the second vertical face adjacent to the second vertical side, or located on the second vertical side; further comprising a passage linking the first plenum chamber to the second plenum chamber located at or adjacent to the mid point between the first and second vertical sides;
and further wherein each of the openings to the plenum chambers and the passage linking the plenum chambers extend for the full height of the door or side panel.

19. A door or panel as claimed in claim 18, wherein the first plenum chamber comprises at least one vertical strip of sound absorbing material extending for the full height of the plenum chamber.

20. A door or panel as claimed in claim 19, wherein the or each vertical strip of sound absorbing material projects into the first plenum chamber to a distance of between 40% and 75% of the width of the chamber.

21. A door or panel as claimed in claim 19 comprising at least one vertical strip of sound absorbing material located on the inside surface of the first vertical face and at least one vertical strip of sound absorbing material located on the opposing face of the partition, the or each vertical strip of sound absorbing material located on the inside surface of the first vertical face being located at a position other than directly opposite a vertical strip of sound absorbing material located on the opposing face of the partition.

22. A door or panel as claimed in claim 21, comprising two vertical strips of sound absorbing material located on the inside surface of the first vertical face, and two vertical strips of sound absorbing material located on the opposing face of the partition, each vertical strip of sound absorbing material projecting into the first plenum chamber to a distance of between 50% and 60% of the width of the chamber.

23. A door or panel as claimed in claim 20 comprising at least one vertical strip of sound absorbing material located on the inside surface of the first vertical face and at least one vertical strip of sound absorbing material located on the opposing face of the partition, the or each vertical strip of sound absorbing material located on the inside surface of the first vertical face being located at a position other than directly opposite a vertical strip of sound absorbing material located on the opposing face of the partition.

24. A door or panel as claimed in claim 23, comprising two vertical strips of sound absorbing material located on the inside surface of the first vertical face, and two vertical strips of sound absorbing material located on the opposing face of the partition, each vertical strip of sound absorbing material projecting into the first plenum chamber to a distance of between 50% and 60% of the width of the chamber.

25. The door or panel of claim 18 wherein at least one of the first and second vertical sides is defined by the opening to the second plenum chamber.

26. A cabinet for storing data processing or telecommunications equipment comprising at least one door or side panel, the door or side panel comprising at least one air passage therethrough defined by:
a first vertical face and an opposing second vertical face;
a first vertical side and an opposing second vertical side;
a first horizontal side and an opposing second horizontal side;
the at least one airflow passage of the door or side panel further defined by at least one partition positioned between the first and second vertical faces, and the at least one air passage arranged so that air may pass through the door or side panel from the first vertical face, past the partition, to the second vertical face, or from the second vertical face, past the partition, to the first vertical face;
wherein a first plenum chamber is formed between the first vertical face and the partition, and a second plenum chamber is formed between the second vertical face and the partition, the first and second plenum chambers being in fluid communication;
the door or side panel further comprising an opening to the first plenum chamber located on the first vertical face adjacent to the first vertical side, or located on the first vertical side, or located at or adjacent to the mid point between the first and second vertical sides, and an opening to the second plenum chamber located on the second vertical face adjacent to the first vertical side, or located on the first vertical side, or located at or adjacent to the mid point between the first and second vertical sides and further comprising a passage linking the first plenum chamber to the second plenum chamber located adjacent to the second vertical side and/or located adjacent to the first vertical side;
or the door or side panel further comprising a first opening to the first plenum chamber located on the first vertical face adjacent to the first vertical side, or located on the first vertical side, and a second opening to the first plenum chamber located on the first vertical face adjacent to the second vertical side, or located on the second vertical side; the door or side panel further comprising a first opening to the second plenum chamber located on the second vertical face adjacent to the first vertical side, or located on the first vertical side, and a second opening to the second plenum chamber located on the second vertical face adjacent to the second vertical side, or located on the second vertical side; further comprising a passage linking the first plenum chamber to the second plenum chamber located at or adjacent to the mid point between the first and second vertical sides;
and further wherein each of the openings to the plenum chambers and the passage linking the plenum chambers extend for the full height of the door or side panel.

27. A cabinet as claimed in claim 26 comprising a first door and opposing second door or wall, the first door comprising two of the panels, and the opposing second door or wall comprising at least one of the panels.

28. A cabinet as claimed in claim 26, wherein the first plenum chamber comprises at least one vertical strip of sound absorbing material extending for the full height of the plenum chamber.

29. A cabinet as claimed in claim 28, wherein the or each vertical strip of sound absorbing material projects into the first plenum chamber to a distance of between 40% and 75% of the width of the chamber.

30. A cabinet as claimed in claim 28 comprising at least one vertical strip of sound absorbing material located on the inside surface of the first vertical face and at least one vertical strip of sound absorbing material located on the opposing face of the partition, the or each vertical strip of sound absorbing material located on the inside surface of the first vertical face being located at a position other than directly opposite a vertical strip of sound absorbing material located on the opposing face of the partition.

31. A door or panel as claimed in claim 30, comprising two vertical strips of sound absorbing material located on the inside surface of the first vertical face, and two vertical strips of sound absorbing material located on the opposing face of the partition, each vertical strip of sound absorbing material projecting into the first plenum chamber to a distance of between 50% and 60% of the width of the chamber.

32. A door or panel as claimed in claim 29 comprising at least one vertical strip of sound absorbing material located on the inside surface of the first vertical face and at least one vertical strip of sound absorbing material located on the opposing face of the partition, the or each vertical strip of sound absorbing material located on the inside surface of the first vertical face being located at a position other than directly opposite a vertical strip of sound absorbing material located on the opposing face of the partition.

33. A door or panel as claimed in claim 32, comprising two vertical strips of sound absorbing material located on the inside surface of the first vertical face, and two vertical strips of sound absorbing material located on the opposing face of the partition, each vertical strip of sound absorbing material projecting into the first plenum chamber to a distance of between 50% and 60% of the width of the chamber.

34. The door or panel of claim 26 wherein at least one of the first and second vertical sides is defined by the opening to the second plenum chamber.
